(19) United States
(12) Patent Application Publication
(10) Pub. No.: US 2018/0108792 A1
(43) Pub. Date: Apr. 19, 2018

(54) SOLAR CELL

(71) Applicant: NEO SOLAR POWER CORP., Hsinchu (TW)

(72) Inventor: Jau-Min DING, Hsinchu (TW)

(21) Appl. No.: 15/786,061

(22) Filed: Oct. 17, 2017

(30) Foreign Application Priority Data
Oct. 19, 2016 (TW) 105133759

(51) Int. Cl. H01L 31/0224; H01L 31/02; H01L 31/05

(52) U.S. Cl. CPC H01L 31/022425; Y02E 10/50; H01L 31/05; H01L 31/02008

(57) ABSTRACT

A solar cell comprising a semiconductor substrate, an intrinsic semiconductor layer, a second conductive type semiconductor layer, a transparent conductive layer, a metal electrode, a light reflective unit, and a transparent packaging layer. The semiconductor substrate has an illuminated surface, which includes an effective absorption region and an ineffective absorption region. The intrinsic semiconductor layer is formed on the illuminated layer. The second conductive type semiconductor layer is formed on the intrinsic semiconductor layer. The transparent conductive layer is formed on the second conductive type semiconductor layer. The metal electrode is located on the transparent conductive layer. The light reflective unit is located on the ineffective absorption region and has a first inclined reflective surface. The transparent packaging layer is located on the transparent conductive layer, the metal electrode, and the light reflective unit.

### BACKGROUND OF INVENTION

### 1. Field of the Invention

The present invention is related to a solar cell, and more particularly is related to a solar cell with a light reflective element located in the ineffective absorption region.

### 2. Description of the Prior Art

Please refer to FIG. 1 and FIG. 2, wherein FIG. 1 is a top view of a conventional heterojunction solar cell, and FIG. 2 is a schematic view showing the structure of the conventional heterojunction solar cell. As shown, the conventional heterojunction solar cell PA100 is composed of a crystalline silicon substrate PA1, an intrinsic amorphous silicon layer PA2, a second conductive type amorphous silicon layer PA3, a transparent conductive layer PA4, a metal electrode PA5, a transparent packaging layer PA6, a transparent glass layer PA7, and a back electrode PA8. During the process of forming the transparent conductive layer PA4 on the second conductive type amorphous silicon layer PA3, in order to prevent the transparent conductive layer PA4 from extending through the edge of the crystalline silicon substrate PA1 to touch the back electrode PA8 at the rear side of the crystalline silicon substrate PA1, a patterned layer would be formed to shield the boundary region of the crystalline silicon substrate PA1 when depositing the transparent conductive layer PA4 so as to prevent the transparent conductive layer PA4 from touching the back electrode PA8 to result in short circuit.

Because the transparent conductive layer PA4 cannot collect the charge carriers generated outside the region covered by the transparent conductive layer PA4 effectively, the crystalline silicon substrate PA1 is divided into the effective absorption region PA11 which can collect the current effectively and the ineffective absorption region PA12 which cannot collect the current effectively according to the allocation of the transparent conductive layer PA4. The ineffective absorption region PA12 occupies a certain portion of the whole illuminated surface of the crystalline silicon substrate PA1, and the area size of the ineffective absorption region PA12 in increasing attending with the increasing number of heterojunction solar cells PA100. Because the solar cell produces the electric energy by converting the light energy absorbed by the illuminated surface, a greater ineffective absorption region PA12 may reduce the produced electric energy relatively.

### SUMMARY OF THE INVENTION

In view of the conventional heterojunction solar cell, because the transparent conductive layer does not fully cover the amorphous silicon layer, some available surface area is wasted such that the electric current produced by photoelectric effect cannot be effectively collected. Accordingly, it is a main object of the present invention to provide a solar cell, which is capable to utilize the light energy collected in the ineffective absorption region so as to increase the produced electric energy of the whole solar cell.

Accordingly, a solar cell is provided in accordance with a main object of the present invention. The solar cell comprises a semiconductor substrate, an intrinsic semiconductor layer, a second conductive type semiconductor layer, a transparent conductive layer, a metal electrode, a light reflective unit, and a transparent packaging layer.

The semiconductor substrate is doped with a first conductive type dopant, and has an illuminated surface. The illuminated surface includes an effective absorption region and an ineffective absorption region surrounding the effective absorption region. The intrinsic semiconductor layer is formed on the illuminated surface. The second conductive type semiconductor layer is formed on the intrinsic semiconductor layer. The second conductive type semiconductor layer is doped with a second conductive type dopant. The transparent conductive layer is formed on the second conductive type semiconductor layer and overlaps the effective absorption region. The transparent conductive layer has an electrode allocation surface.

The metal electrode is located on the electrode allocation surface. The light reflective unit is located on the ineffective absorption region, and has a first inclined reflective surface, which is inclined toward the effective absorption region. The transparent packaging layer is located on the transparent conductive layer, the metal electrode and the light reflective unit. The transparent packaging layer includes an interface in contact with air.

Wherein, as a light beam propagating along an incident direction perpendicular to the illuminated surface is reflected by the first inclined reflective surface toward the effective absorption region, the light beam would be projected to the air/transparent-packaging-layer interface and reflected by the interface back to the transparent conductive layer.

In accordance with an embodiment of the solar cell of the present invention, the light reflective unit further has a horizontal surface. The horizontal surface is parallel to the illuminated surface and overlaps a bottom edge of the first inclined reflective surface. A first inclined angle is formed between the first inclined reflective surface and the horizontal surface. The first inclined angle is ranged between 20 degrees and 45 degrees.

In accordance with an embodiment of the present invention, the light reflective unit further has a second inclined reflective surface. The second inclined reflective surface is inclined toward the effective absorption region and located opposite to the first inclined reflective surface. A second inclined angle is formed between the second inclined reflective surface and the horizontal surface. The second inclined angle is ranged between 20 degrees and 89 degrees.

In accordance with an embodiment of the present invention, the light reflective unit further has a third reflective surface. The third inclined reflective surface is located between the first inclined reflective surface and the second inclined reflective surface. The third inclined reflective surface is inclined away from the effective absorption region. A third inclined angle is formed between the third inclined reflective surface and the horizontal surface. When a sum of the third inclined angle and double the second inclined angle is greater than 90 degrees, a sum of the third inclined angle and the second inclined angle would be ranged between 45 degrees and 70 degrees. As a preferred embodiment, the sum of the third inclined angle and the second inclined angle is ranged between 50 degrees and 65 degrees.

In accordance with an embodiment of the present invention, the semiconductor substrate is a crystalline silicon substrate, the intrinsic semiconductor layer is an intrinsic amorphous silicon layer, the second conductive type semiconductor layer is a second conductive type amorphous silicon layer.

In accordance with an embodiment of the present invention, the light reflective unit is formed on the second conductive type semiconductor layer and located in the ineffective absorption region.

In accordance with an embodiment of the present invention, the intrinsic semiconductor layer is formed on the illuminated surface and located in the effective absorption region, and the light reflective unit is formed on the illuminated surface and located in the ineffective absorption region.

In accordance with an embodiment of the present invention, the metal electrode includes a busbar, and the solar cell further comprises a busbar reflective unit which is located on the busbar.

In accordance with an embodiment of the present invention, the light reflective unit is adhered to the ineffective absorption region.

In accordance with an embodiment of the present invention, the first inclined reflective surface has a reflective coating.

In accordance with an embodiment of the present invention, the reflective coating is selected from a group composed of Al, Ag, Sn, and a composition thereof.

Another solar cell is also provided in accordance with a main object of the present invention. The solar cell comprises a semiconductor substrate, an intrinsic semiconductor layer, a second conductive type semiconductor layer, a transparent conductive layer, a metal electrode, a light reflective unit, and a transparent packaging layer.

The semiconductor substrate is doped with a first conductive type dopant, and has an illuminated surface. The illuminated surface includes an effective absorption region and an ineffective absorption region surrounding the effective absorption region. The intrinsic semiconductor layer is formed on the illuminated surface. The second conductive type semiconductor layer is formed on the intrinsic semiconductor layer. The second conductive type semiconductor layer is doped with a second conductive type dopant. The transparent conductive layer is formed on the second conductive type semiconductor layer, and overlaps the effective absorption region. The transparent conductive layer has an electrode allocation surface. The metal electrode is located on the electrode allocation surface.

The light reflective unit is located on the ineffective absorption region, and has a first inclined reflective surface, which is inclined toward the effective absorption region. The transparent packaging layer is located on the transparent conductive layer, the metal electrode and the light reflective unit.

Wherein, as a light beam propagating along an incident direction perpendicular to the illuminated surface is projected to the first inclined reflective surface, the light beam is reflected by the first inclined reflective surface toward the transparent conductive layer.

In accordance with an embodiment of the aforementioned solar cell, the light reflective unit has a horizontal surface. The horizontal surface is parallel to the illuminated surface and overlaps a bottom edge of the first inclined reflective surface. A first inclined angle is formed between the first inclined reflective surface and the horizontal surface. The first inclined angle is ranged between 20 degrees and 45 degrees.

In accordance with an embodiment of the aforementioned solar cell, the light reflective unit further has a second inclined reflective surface. The second inclined reflective surface is inclined toward the effective absorption region and located opposite to the first inclined reflective surface. A second inclined angle is formed between the second inclined reflective surface and the horizontal surface. The second inclined angle is ranged between 20 degrees and 89 degrees.

In accordance with an embodiment of the aforementioned solar cell, the light reflective unit further has a third reflective surface. The third inclined reflective surface is located between the first inclined reflective surface and the second inclined reflective surface. The third inclined reflective surface is inclined away from the effective absorption region. A third inclined angle is formed between the third inclined reflective surface and the horizontal surface. When a sum of the third inclined angle and double the second inclined angle is greater than 90 degrees, a sum of the third inclined angle and the second inclined angle would be ranged between 45 degrees and 70 degrees.

In accordance with an embodiment of the aforementioned solar cell, the semiconductor substrate is a crystalline silicon substrate, the intrinsic semiconductor layer is an intrinsic amorphous silicon layer, the second conductive type semiconductor layer is a second conductive type amorphous silicon layer.

In accordance with an embodiment of the aforementioned solar cell, the light reflective unit is formed on the second conductive type semiconductor layer and located in the ineffective absorption region.

In accordance with an embodiment of the aforementioned solar cell, the intrinsic semiconductor layer is formed on the illuminated surface and located in the effective absorption region, and the light reflective unit is formed on the illuminated surface and located in the ineffective absorption region.

In accordance with an embodiment of the aforementioned solar cell, the metal electrode includes a busbar, and the solar cell further comprises a busbar reflective unit which is located on the busbar.

In accordance with an embodiment of the aforementioned solar cell, the light reflective unit is adhered to the ineffective absorption region.

In accordance with an embodiment of the aforementioned solar cell, the first inclined reflective surface has a reflective coating.

In accordance with an embodiment of the aforementioned solar cell, the reflective coating is selected from a group composed of Al, Ag, Sn, and a composition thereof.

As mentioned, the conventional heterojunction solar cell cannot collect the light energy received at the ineffective absorption region. In contrast, the solar cell provided in accordance with the present invention places the light reflective unit located in the ineffective absorption region to reflect the incident light beam to the effective absorption region to enhance light absorption of the solar cell such that the produced electric energy can be increased.

### BRIEF DESCRIPTION OF THE DRAWINGS

The present invention will now be specified with reference to its preferred embodiment illustrated in the drawings, in which:

FIG. 1 is a top view of a conventional heterojunction solar cell;

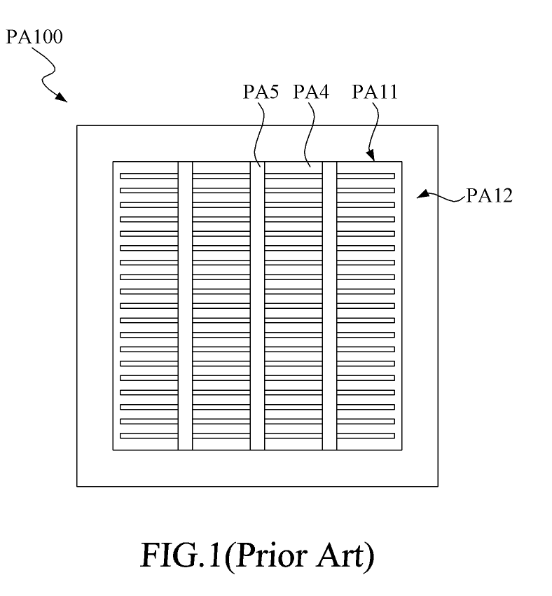

FIG. 2 is a schematic view showing the structure of a conventional heterojunction solar cell;

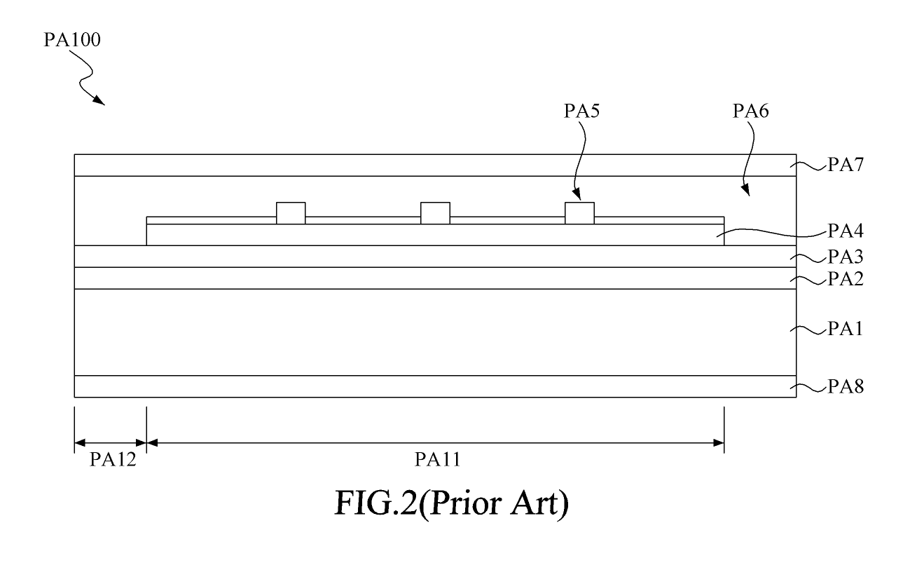

FIG. 3 is a 3D schematic view of a solar cell provided in accordance with a first preferred embodiment of the present invention;

FIG. 4 is a schematic view showing the structure of the solar cell provided in accordance with a first preferred embodiment of the present invention;

FIG. 4A is an enlarged view of a portion of FIG. 4;

FIG. 5 is a schematic view showing the structure of the solar cell provided in accordance with a second preferred embodiment of the present invention;

FIG. 6 is a schematic view showing the structure of the solar cell provided in accordance with a third preferred embodiment of the present invention;

FIG. 6A is an enlarged view of a portion of FIG. 6;

FIG. 7 is a schematic view showing the structure of the solar cell provided in accordance with a fourth preferred embodiment of the present invention;

FIG. 7A is an enlarged view of a portion of FIG. 7;

FIG. 8 is a schematic view showing the structure of the solar cell provided in accordance with a fifth preferred embodiment of the present invention;

FIG. 8A is an enlarged view of a portion of FIG. 8;

FIG. 9 is a schematic view showing the structure of the solar cell provided in accordance with a sixth preferred embodiment of the present invention;

FIG. 9A is an enlarged view of a portion of FIG. 9;

FIG. 9B is an enlarged view of another portion of FIG. 9;

FIG. 10 is a schematic view showing the structure of the solar cell provided in accordance with a seventh preferred embodiment of the present invention;

FIG. 11 is a top view of the solar cell provided in accordance with an eighth preferred embodiment of the present invention;

FIG. 12 is a schematic view showing the structure of the solar cell provided in accordance with the eighth preferred embodiment of the present invention; and

FIG. 12A is an enlarged view of the region A in FIG. 12.

### DESCRIPTION OF THE PREFERRED EMBODIMENT

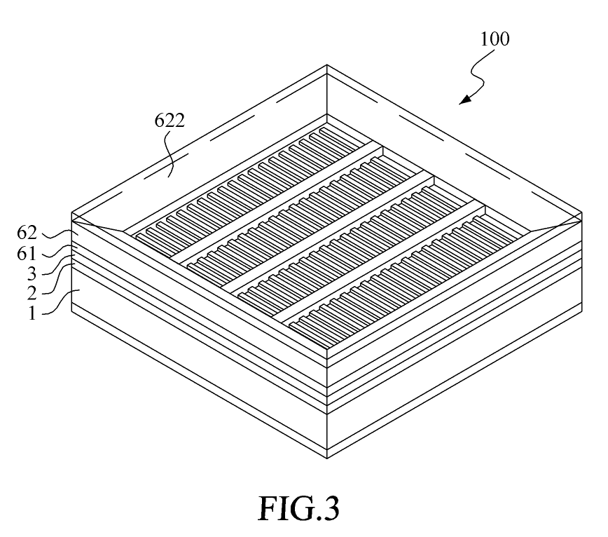

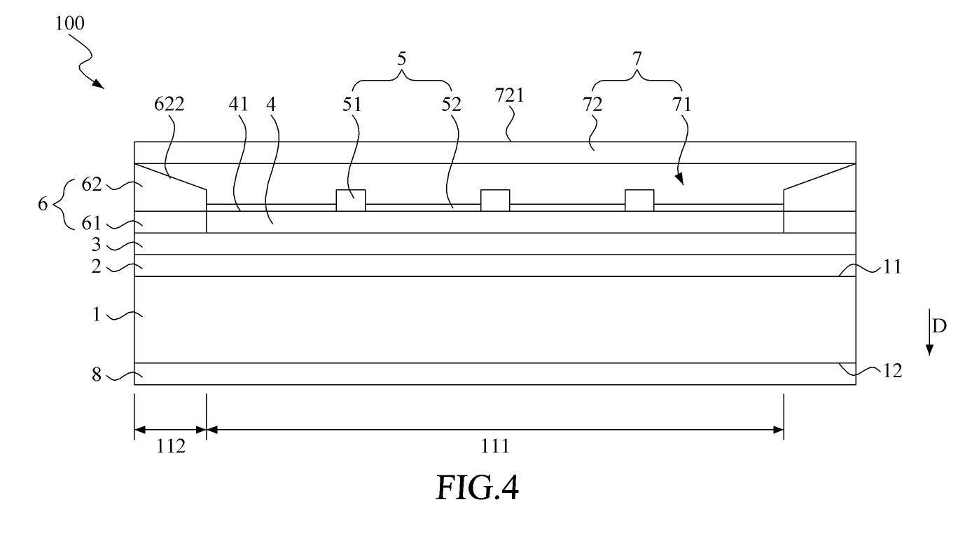

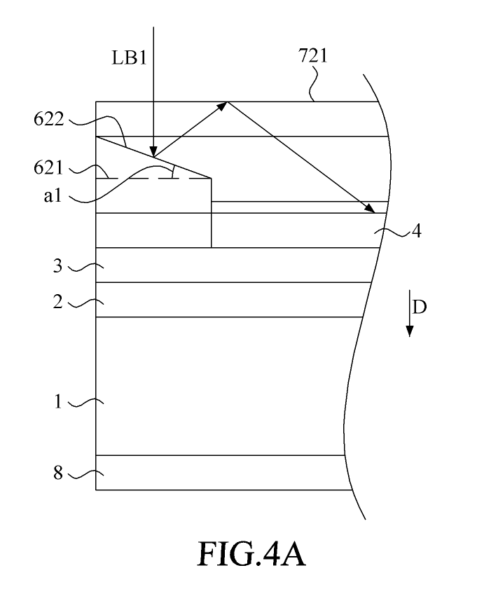

Please refer to FIGS. 3 to 4A, wherein FIG. 3 is a 3D schematic view of a solar cell provided in accordance with a first preferred embodiment of the present invention, FIG. 4 is a schematic view showing the structure of the solar cell provided in accordance with a first preferred embodiment of the present invention, and FIG. 4A is an enlarged view of a portion of FIG. 4. As shown, the solar cell 100 includes a semiconductor substrate 1, an intrinsic semiconductor layer 2, a second conductive type semiconductor layer 3, a transparent conductive layer 4, a metal electrode 5, a light reflective unit 4, a transparent packaging layer 7, and a back electrode 8.

The semiconductor substrate 1 is doped with a first conductive type dopant, and the semiconductor substrate 1 has an illuminated surface 11 and a back surface 12 opposite to the illuminated surface 11. The illuminated surface 11 includes an effective absorption region 111 and an ineffective absorption region 112 surrounding the effective absorption region 111. The first conductive type mentioned in the present embodiment is n-type for example.

The intrinsic semiconductor layer 2 is formed on the illuminated surface 11. In practice, the intrinsic semiconductor layer 2 of the present embodiment can be an amorphous semiconductor layer without p-type or n-type dopants. However, the present invention should not be restricted thereby. In the other embodiments, the intrinsic semiconductor layer 2 can be a lightly-doped p-type amorphous semiconductor layer or a lightly-doped n-type amorphous semiconductor layer with a dopant concentration from 1×10¹⁴ to 1×10¹⁶ atoms/cm³. The second conductive type semiconductor layer 3 is formed on the intrinsic semiconductor layer 2. The second conductive type semiconductor layer 3 is doped with a second conductive type dopant. The second conductive type mentioned in the present embodiment is P type for example. In practice, the intrinsic semiconductor layer 2 and the second conductive type semiconductor layer 3 can be formed by using plasma-enhanced chemical vaper deposition (PECVD), and the intrinsic semiconductor layer 2 can be an amorphous semiconductor layer without p-type or n-type dopant.

The transparent conductive layer 4 is formed on the second conductive type semiconductor layer 3 and overlaps the effective absorption region 111. The transparent conductive layer 4 has an electrode allocation surface 41. In practice, the transparent conductive layer 4 can be a transparent conductive oxide thin film formed by using sputtering or PECVD. The transparent conductive layer 4 may be formed by using the material such as ITO, ITiO, IMO, IWO, ICeO, IGZO, AZO, GZO or IZO.

The metal electrode 5 is located on the electrode allocation surface 41. The metal electrode 5 includes three busbars 51 (only one of them is labelled) and a plurality of finger-shaped electrode portions 52 (only one of them is labelled) perpendicularly extended from the opposite sides of the busbar 51.

The light reflective unit 6 includes an adhering layer 61 and a reflective structure 62. The adhering layer 61 is formed on the portion of the intrinsic semiconductor layer 2 corresponding to the ineffective absorption region 112. The reflective structure 62 is placed on the adhering layer 61 such that the reflective structure 62 can be fixed on the portion of the intrinsic semiconductor layer 2 corresponding to the ineffective absorption region 112 by the adhering layer 61. The adhering layer 61 may be formed by using pressure-sensitive adhesive, hot melt adhesive or chemically curing adhesive. But the present invention is not restricted thereby.

The reflective structure 62 includes a horizontal surface 621 and a first inclined reflective surface 622. The horizontal surface 621 is parallel to the illuminated surface 11. The distance between the horizontal surface 621 and the illuminated surface 11 is greater than the distance between the electrode allocation surface 41 and the illuminated surface 11. The first inclined reflective surface 622 is inclined toward the effective absorption region 111, and the bottom edge of the first inclined reflective surface 622 overlaps the horizontal surface 621. A first inclined angle a1 is formed between the first inclined reflective surface 622 and the horizontal surface 621. The first inclined angle a1 is ranged between 20 degrees and 45 degrees, and the range between 25 degrees and 40 degrees is preferred. In the present embodiment, the first inclined angle is 20 degrees. In addition, the reflective structure 62 may be formed by using the metal material such as Al, Ag, or Sn.

The transparent packaging layer 7 includes a transparent packaging adhesive layer 71 and a transparent substrate 72. The transparent packaging adhesive layer 71 is formed on the transparent conductive layer 4, the metal electrode 5, and the light reflective unit 6. The transparent packaging adhesive layer 71 is composed of a transparent insulating material, such as Ethylene Vinyl Acetate (EVA) in the present embodiment. The transparent substrate 72 is located on the transparent packaging adhesive layer 71 to seal the transparent conductive layer 4, the metal electrode 5, and the light reflective unit 6 by the firmly connection of the transparent packaging adhesive layer 71. The transparent substrate 72 includes an interface in contact with the air. The transparent substrate 72 can be a glass substrate for example.

The back electrode 8 is formed on the back surface 12. The back electrode 8 can be a transparent conductive oxide thin film for example.

As mentioned, as an incident light beam LB1 propagates along an incident direction D perpendicular to the illuminated surface 11 to the first inclined reflective surface 622, the incident light beam LB1 would be reflected by the first inclined reflective surface 622 toward the space above the effective absorption region 111, and the incident light beam LB1 would be further reflected by the air/transparent-packaging-layer interface 721 back to the transparent conductive layer 4. Then, the light beam LB1 would penetrate the transparent conductive layer 4 and be absorbed by the semiconductor substrate 1, the intrinsic semiconductor layer 2, and the second conductive type semiconductor layer 3.

In practice, as the transparent packaging layer 71 is composed of EVA, which has a refractive index of about 1.52, and the transparent substrate 72 is a glass substrate, which has a refractive index of about 1.52, the transparent packaging layer 71 and the transparent substrate 72 can be deemed as the same optical medium. After the light beam LB1 is reflected by the first inclined reflective surface 622, the light beam LB1 would pass through the transparent packaging layer 71 and the transparent substrate 72 to the air/transparent-packaging-layer interface 721. Because the refractive index of the transparent substrate 72 (e.g. 1.52 for the glass substrate) is much greater than the refractive index of the air, which is about 1, the light beam LB1 projected to the air/transparent-packaging-layer interface 721 would be reflected and refracted by the air/transparent-packaging-layer interface 721 depends on the incident angle. As the incident angle of the light beam LB1 projected to the air/transparent-packaging-layer interface 721 is greater than the critical angle, total reflection would occur, such that the light absorption rate of the semiconductor substrate 1, the intrinsic semiconductor layer 2, and the second conductive type semiconductor layer 3 can be effectively enhanced. In addition, because reflective index has little relevance to the variation of wave length, in the present embodiment, the incident light beam LB1 with the wave length from 380 nm to 1100 nm can be used to be reflected by the first inclined reflective surface 622 and the air/transparent-packaging-layer interface 721 to the semiconductor substrate 1, the intrinsic semiconductor layer 2, and the second conductive type semiconductor layer 3. However, the scope of the present invention should not be restricted thereby. In practice, the light beams with the wave length capable to be absorbed by the semiconductor substrate 1 can be used in the present invention.

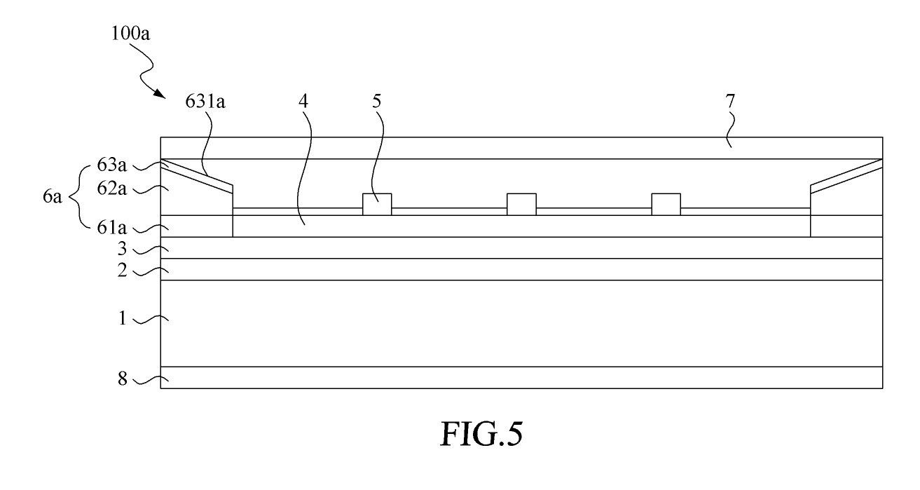

Please further refer to FIG. 5, which is a schematic view showing the structure of the solar cell in accordance with a second preferred embodiment of the present invention. As shown, the solar cell 100a is similar to the solar cell 100 provided in accordance with the first preferred embodiment. The major difference between the two embodiments is that the light reflective unit 6 in the first preferred embodiment is replaced by the light reflective unit 6a of the solar cell 100a.

The light reflective unit 6a includes an adhering layer 61a, a molded structure 62a, and a reflective coating 63a. The adhering layer 61a is formed on the second conductive type semiconductor layer 3, the molded structure 62a is located on the adhering layer 61a so as to be fixed on the second conductive type semiconductor layer 3, and the reflective coating 63a is formed on the molded structure 62a. The molded structure 62a may be composed of thermosetting polymer or the polymer material with high glass transition temperature, such as epoxy. The reflective coating 63a can be a metal thin film composed of Al, Ag, Sn or other metal materials. In the present embodiment, the molded structure 62a can be a non-reflective structure with the reflective coating 63a thereon to form the inclined reflective surface 631a to reflect the vertical incident light beam LB1. In practice, the reflective coating 63a may be formed on the molded structure 62a by using evaporation or sputtering.

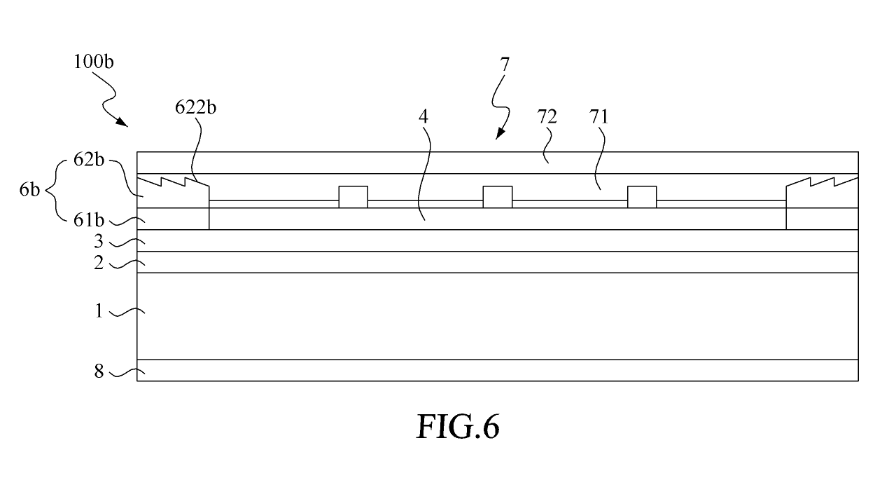

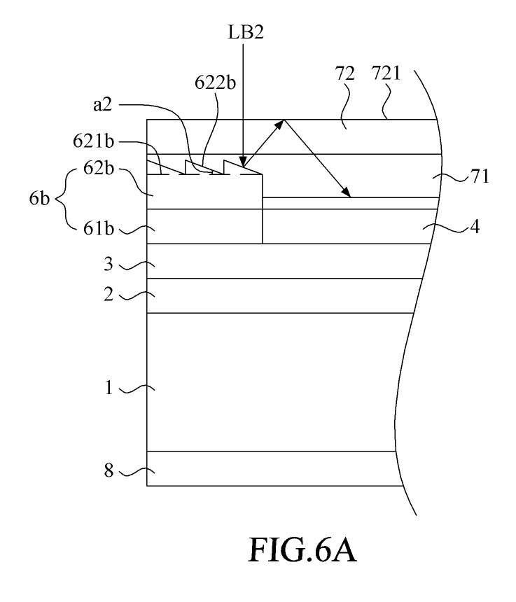

Please refer to FIG. 6 and FIG. 6A, wherein FIG. 6 is a schematic view showing the structure of the solar cell provided in accordance with a third preferred embodiment of the present invention, and FIG. 6A is an enlarged view of a portion of FIG. 6. As shown, the solar cell 100b is similar to the solar cell 100 provided in accordance with the first preferred embodiment. The major difference between the two embodiments is that the light reflective unit 6 in the first preferred embodiment is replaced by the light reflective unit 6b of the solar cell 100b.

The light reflective unit 6b includes an adhering layer 61b and a light reflective structure 62b. The adhering layer 61b is formed on the second conductive type semiconductor layer 3, and the light reflective structure 62b is located on the adhering layer 61b. The light reflective structure 62b has a horizontal surface 621b and three first inclined reflective surfaces 622b (only one of them is labelled). These first inclined reflective surfaces 622b are all inclined toward the effective absorption region (corresponding to the effective absorption region 111 mentioned above), and a first inclined angle a2 is formed between each of the first inclined reflective surface 622b and the horizontal surface 621b. The first inclined angle a2 is ranged between 20 degrees and 89 degrees, and the range between 25 degrees and 50 degrees is preferred. In the present embodiment, the first inclined angle a2 is 40 degrees.

As mentioned, the present embodiment splits the aforementioned first inclined reflective surface 622 into several first inclined reflective surfaces 622b with identical inclined angle and has the first inclined angle a2 between the first reflective surface 622b and the horizontal surface 621b kept at 40 degrees. Thereby, the vertical incident light beam LB2 can be reflected by the first inclined reflective surfaces 622b to the air/transparent-packaging-layer interface 721 effectively such that the overall height of the light reflective structure 62b can be reduced to prevent excessive increasing of overall thickness of the solar cell 100b.

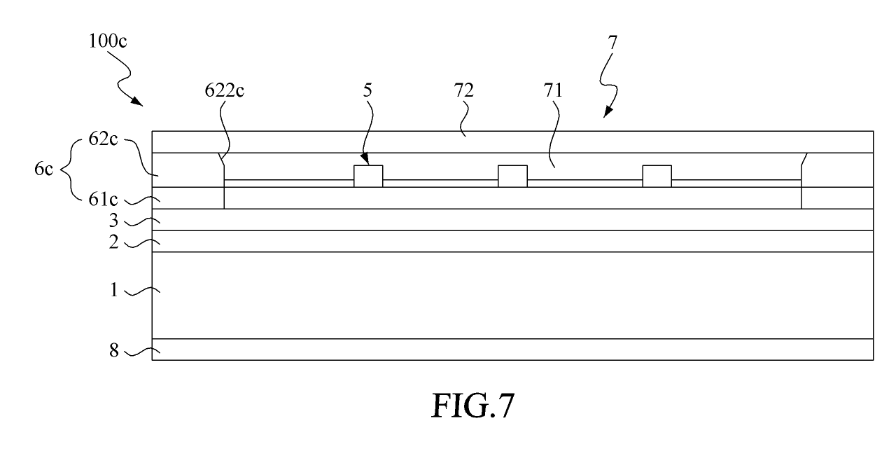

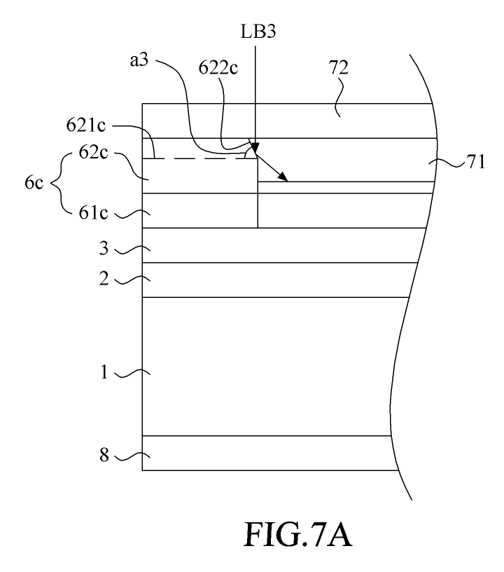

Please refer to FIG. 7 and FIG. 7A, wherein FIG. 7 is a schematic view showing the structure of the solar cell provided in accordance with a fourth preferred embodiment of the present invention, and FIG. 7A is an enlarged view of a portion of FIG. 7. As shown, the solar cell 100c is similar to the solar cell 100 provided in accordance with the first preferred embodiment. The major difference between the two embodiments is that the light reflective unit 6 in the first preferred embodiment is replaced by the light reflective unit 6c of the solar cell 100c.

The light reflective unit 6c includes an adhering layer 61c and a light reflective structure 62c. The adhering layer 61c is formed on the second conductive type semiconductor layer 3, and the light reflective structure 62c is located on the adhering layer 61c. The light reflective structure 62c has a horizontal surface 621c and a first inclined reflective surfaces 622c. There first inclined reflective surface 622c is inclined toward the effective absorption region (corresponding to the effective absorption region 111 mentioned above), and a first inclined angle a3 is formed between the first inclined reflective surface 622c and the horizontal surface 621c. The first inclined angle a3 is ranged between 45 degrees and 89 degrees. In the present embodiment, the first inclined angle a3 is 70 degrees.

As mentioned, in the present embodiment, the first inclined angle a3 between the first inclined reflective surface 622c and the horizontal surface 621c is kept in the range between 45 degrees and 89 degrees such that the vertical incident light beam LB3 can be effectively reflected to the semiconductor substrate 1 directly to reduce the light path length of the vertical light beam LB3 entering the semiconductor substrate 1.

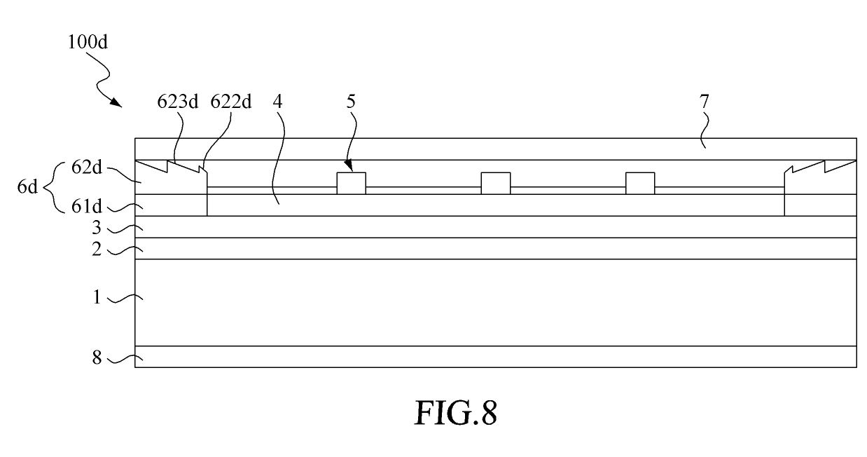

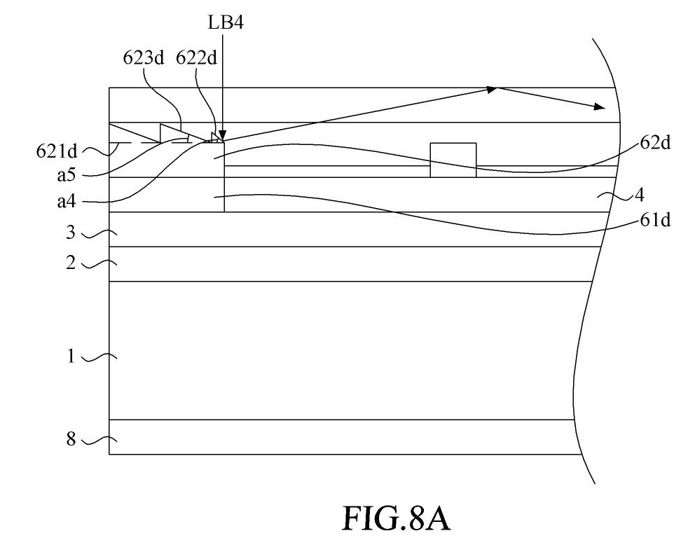

Please refer to FIG. 8 and FIG. 8A, wherein FIG. 8 is a schematic view showing the structure of the solar cell provided in accordance with a fifth preferred embodiment of the present invention, and FIG. 8A is an enlarged view of a portion of FIG. 8. As shown, the solar cell 100d is similar to the solar cell 100 provided in accordance with the first preferred embodiment. The major difference between the two embodiments is that the light reflective unit 6 in the first preferred embodiment is replaced by the light reflective unit 6d of the solar cell 100d.

The light reflective unit 6d includes an adhering layer 61d and a light reflective structure 62d. The adhering layer 61d is formed on the second conductive type semiconductor layer 3, and the light reflective structure 62d is located on the adhering layer 61d. The light reflective structure 62d has a horizontal surface 621b, a first inclined reflective surface 622d, and two second inclined reflective surfaces 623d (only one of them is labelled). The first inclined reflective surface 622d is inclined toward the effective absorption region (corresponding to the effective absorption region 111 mentioned above), and a first inclined angle a4 is formed between the first inclined reflective surface 622d and the horizontal surface 621d. The second inclined reflective surface 623d is located opposite to the first inclined reflective surface 622d with respective to the effective absorption region (corresponding to the effective absorption region 111 mentioned above) and is inclined away from the effective absorption region. A second inclined angle a5 is formed between the second inclined reflective surface 623d and the horizontal surface 621d. The first inclined angle a4 is ranged between 20 degrees and 45 degrees, and the second inclined angle a5 is ranged between 20 degrees and 89 degrees. In the present embodiment, the first inclined angle a4 is 40 degrees, and the second inclined angle a5 is 20 degrees.

As mentioned, the present embodiment splits the aforementioned first inclined reflective surface 622 into several reflective surfaces, has the first inclined angle a4 between the first inclined reflective surface 622d and the horizontal surface 621d kept at 40 degrees, and has the second inclined angle a5 between the second inclined reflective surface 623d and the horizontal surface 621d kept at 20 degrees. Thereby, the vertical incident light beam LB4 not only can be effectively reflected to the semiconductor substrate 1 directly by using the first inclined reflective surface 622d, but also can be effectively reflected to the air/transparent-packaging-layer interface 721 by using the second inclined reflective surfaces 623d (the light path is similar to the reflecting path of the vertical incident light beam LB2 in FIG. 6A), such that the overall height of the light reflective structure 62d can be reduced to prevent excessive increasing of overall thickness of the solar cell 100d.

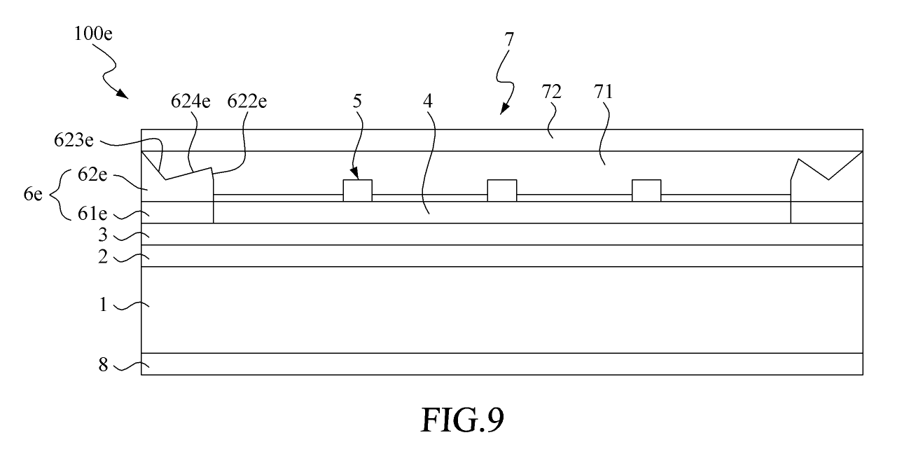

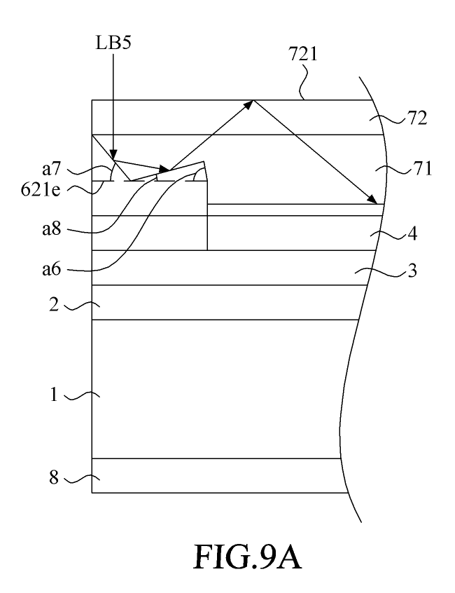

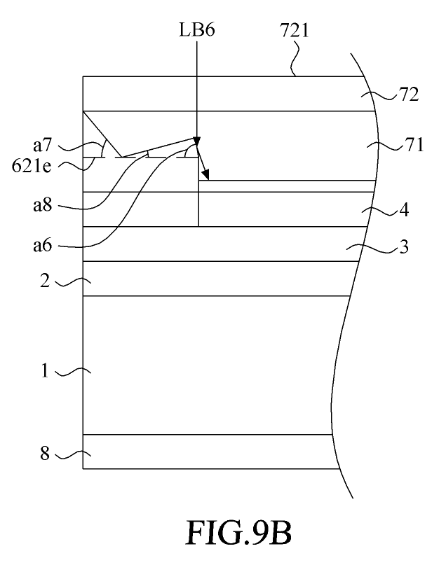

Please refer to FIG. 9 and FIG. 9A, wherein FIG. 9 is a schematic view showing the structure of the solar cell provided in accordance with a sixth preferred embodiment of the present invention, and FIG. 9A is an enlarged view of a portion of FIG. 9. As shown, the solar cell 100e is similar to the solar cell 100 provided in accordance with the first preferred embodiment. The major difference between the two embodiments is that the light reflective unit 6 in the first preferred embodiment is replaced by the light reflective unit 6e of the solar cell 100e.

The light reflective unit 6e includes an adhering layer 61e and a light reflective structure 62e. The adhering layer 61e is formed on the second conductive type semiconductor layer 3, and the light reflective structure 62e is located on the adhering layer 61e. The light reflective structure 62e has a horizontal surface 621e, a first inclined reflective surface 622e, a second inclined reflective surface 623e, and a third inclined reflective surfaces 624e. The first inclined reflective surface 622e is inclined toward the effective absorption region (corresponding to the effective absorption region 111 mentioned above), and a first inclined angle a6 is formed between the first inclined reflective surface 622e and the horizontal surface 621e. The second inclined reflective surface 623e is located opposite to the first inclined reflective surface 622e with respective to the effective absorption region and is inclined toward the effective absorption region. A second inclined angle a7 is formed between the second inclined reflective surface 623e and the horizontal surface 621e. The third inclined reflective surface 624e is located between the first inclined reflective surface 622e and the second inclined reflective surface 623e, and is inclined away from the effective absorption region. A third inclined angle a8 is formed between the third inclined reflective surface 624e and the horizontal surface 621e. As the sum of the third inclined angle a8 and double the second inclined angle a7 is greater than 90 degrees, the sum of the third inclined angle a8 and the second inclined angle a7 should be ranged between 45 degrees and 70 degrees.

In the present embodiment, the first inclined angle a6 is 80 degrees, the second inclined angle a7 is 50 degrees, and the third inclined angle a8 is 15 degrees. That is, because the second inclined angle is 50 degrees, the sum of double the second inclined angle a7, i.e. 100 degrees, and the third inclined angle a8, i.e. 15 degrees, is 115 degrees, which is greater than 90 degrees. Meanwhile, the sum of the third inclined angle a8, i.e. 15 degrees, and the second inclined angle a7, i.e. 50 degrees, is 65 degrees, which is ranged between 45 degrees and 70 degrees. Therefore, the vertical incident light beam LB5 projected to the second inclined reflective surface 623e would be reflected to the third inclined reflective surface 624e, and further reflected by the air/transparent-packaging-layer interface 721 toward the semiconductor substrate 1.

In addition, as the vertical incident light beam LB6 is projected to the first inclined reflective surface 622e, because the first inclined angle a6 is 80 degrees, which is greater than 45 degrees, the vertical incident light beam LB6 would be reflected toward the semiconductor substrate 1 directly. Thereby, the solar cell 100e provided in the present embodiment not only can project the incident light beam LB5 to the semiconductor substrate 1 through the reflection of the second inclined reflective surface 623e, the third inclined reflective surface 624e, and the air/transparent-packaging-layer interface 721, but also can project the vertical incident light beam LB6 to the semiconductor substrate 1 through the reflection of the first inclined reflection surface 622e such that light absorption of the solar cell 100e can be enhanced, and thus the conversion rate can be enhanced.

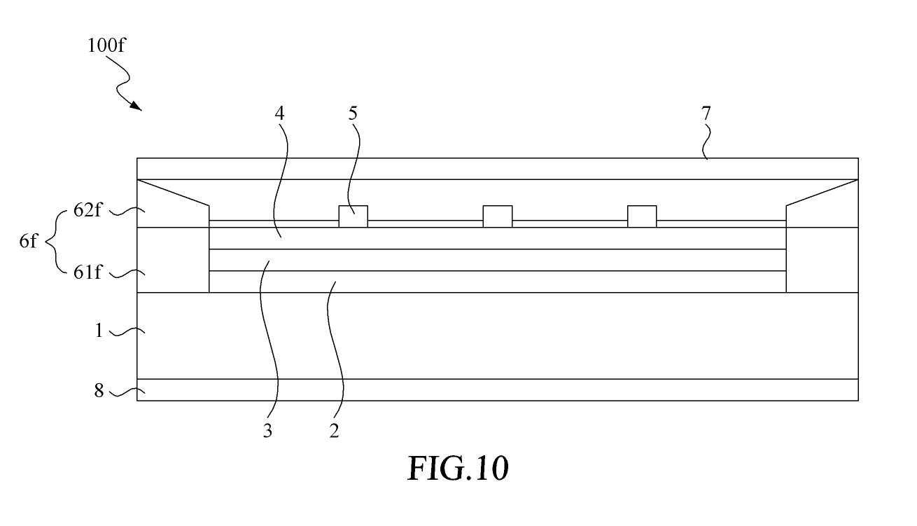

Please refer to FIG. 4 and FIG. 10, wherein FIG. 10 is a schematic view showing the structure of the solar cell provided in accordance with a sixth preferred embodiment of the present invention. As shown, the solar cell 100f is similar to the solar cell 100 provided in accordance with the first preferred embodiment. The major difference between the two embodiments is that the light reflective unit 6 in the first preferred embodiment is replaced by the light reflective unit 6f of the solar cell 100f.

The light reflective unit 6f includes an adhering layer 61f and a light reflective structure 62f. The adhering layer 61f is formed on the semiconductor substrate 1, and the light reflective structure 62f is located on the adhering layer 61f so as to be fixed to the ineffective absorption region 112 of the illuminated surface 11 of the semiconductor substrate 1 through the adhering layer 61f. In addition, in the present embodiment, the intrinsic semiconductor layer 2 is formed on the effective absorption region 111 of the illuminated surface 11. The second conductive type semiconductor layer 3 and the transparent conductive layer 4 serially stacked on the intrinsic semiconductor layer 2 are also located in the effective absorption region 111.

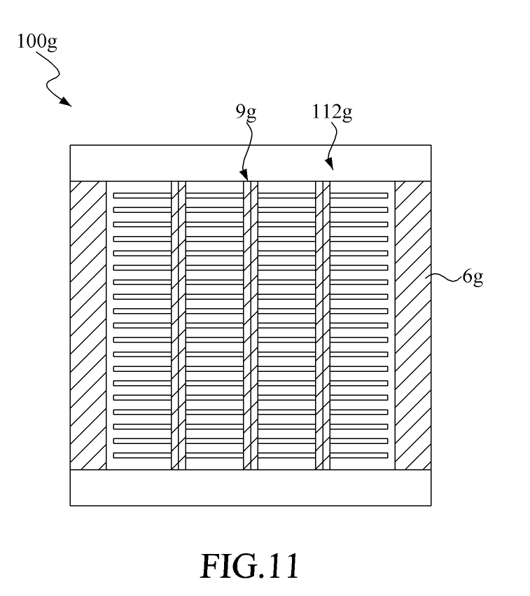

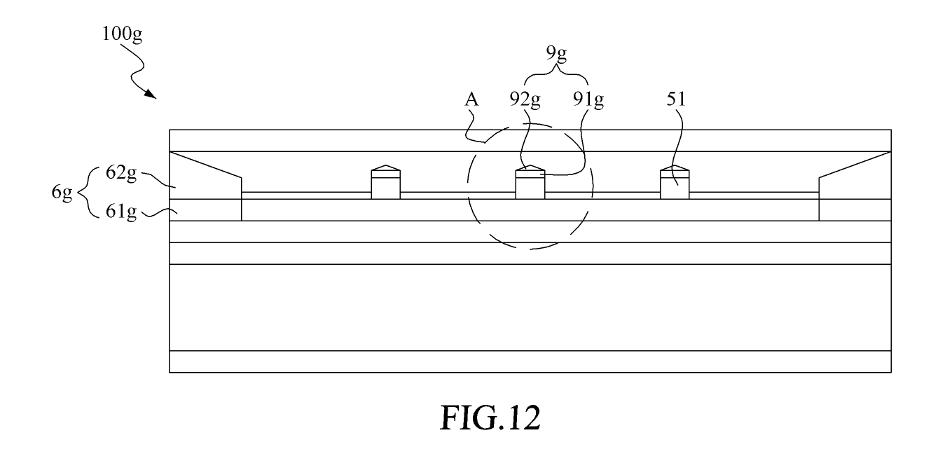

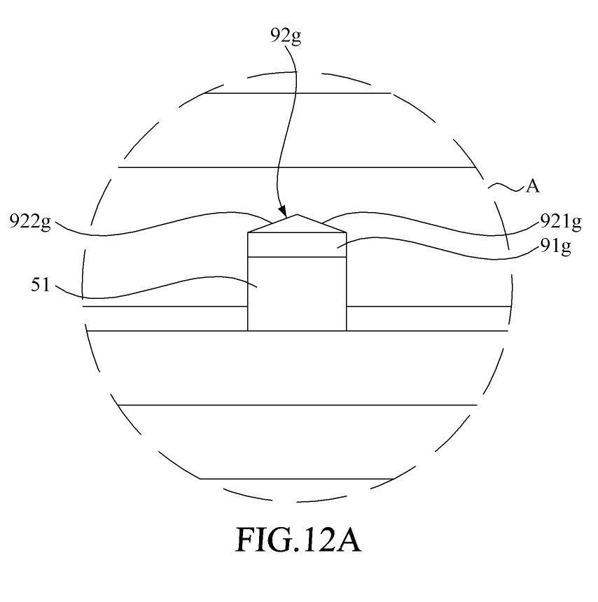

Please refer to FIG. 11 to FIG. 12A, wherein FIG. 11 is a top view of the solar cell provided in accordance with an eighth preferred embodiment of the present invention, FIG. 12 is a schematic view showing the structure of the solar cell provided in accordance with the eighth preferred embodiment of the present invention, and FIG. 12A is an enlarged view of the region A in FIG. 12.

As shown, the solar cell 100g is similar to the solar cell 100 provided in accordance with the first preferred embodiment. The major difference between the two embodiments is that the light reflective unit 69 of the solar cell 100g is located at the opposite sides of the ineffective absorption region 112g parallel to the busbar 51, and the solar cell 100g includes three busbar reflective units 9g in addition to one light reflective unit 6g.

The light reflective unit 6g includes an adhering layer 61g and a light reflective structure 62g. The light reflective unit 6g is corresponding to the light reflective unit 6 mentioned above, and thus is not repeated here. Each of the busbar reflective unit 9g includes an adhering layer 91g and a light reflective structure 92g. The adhering layer 91g is formed on the busbar 51, and the light reflective structure 92g is located on the adhering layer 91g. The light reflective structure 92g includes a first inclined reflective surface 921g and a second inclined reflective surface 922g. As a vertical incident light beam (not shown) is projected to the first inclined reflective surface 921g and the second inclined reflective surface 922g, the light beam would be reflected to the air/transparent-packaging-layer interface 721 and further reflected to the effective absorption region (not shown, but corresponding to the effective absorption region 111). The first inclined reflective surface 921g and the second inclined reflective surface 922g have the first inclined angle and the second inclined angle with respective to the horizontal surface respectively. In the present embodiment, the first inclined reflective angle and the second inclined reflective angle are both 20 degrees.

In conclusion, in compared with the conventional solar cell, which cannot utilize the incident light beam received in the ineffective absorption region, the present invention has the light reflective unit located in the ineffective absorption region to reflect the incident light beam projected to the ineffective absorption region to the effective absorption region directly or indirectly, such that the light beam can be absorbed by the semiconductor substrate, the intrinsic semiconductor layer, and the second conductive type semiconductor layer to increase light absorption and also the produced electricity. In addition, the present invention also has the busbar reflective unit located on the busbar to reflect to light beam which would be blocked by the busbar to the effective absorption region to further enhance light absorption of the solar cell.

As mentioned, when the first inclined angle of the first inclined reflective surface is ranged between 20 degrees and 45 degrees, the first inclined reflective surface would reflect the vertical incident light beam to the air/transparent-packaging-layer interface, and the light beam would be further reflected to the semiconductor substrate by the air/transparent-packaging-layer interface. When the first inclined angle of the first inclined reflective surface is ranged between 45 degrees and 89 degrees, the vertical incident light beam would be reflected by the first inclined reflective surface and projected to the semiconductor substrate directly.

In addition, the present invention may further split the light reflective unit into several first inclined reflective surfaces, or into the first inclined reflective surface, the second inclined reflective surface or further the third inclined reflective surface to increase the amount of vertical incident light beam reflected to the effective absorption region.

While the present invention has been particularly shown and described with reference to a preferred embodiment, it will be understood by those skilled in the art that various changes in form and detail may be without departing from the spirit and scope of the present invention.

What is claimed is:

1. A solar cell, comprising:
a semiconductor substrate, doped with a first conductive type dopant, and having an illuminated surface, the illuminated surface including an effective absorption region and an ineffective absorption region surrounding the effective absorption region;
an intrinsic semiconductor layer, formed on the illuminated surface;
a second conductive type semiconductor layer, formed on the intrinsic semiconductor layer, and the second conductive type semiconductor layer being doped with a second conductive type dopant;
a transparent conductive layer, formed on the second conductive type semiconductor layer, and overlapping the effective absorption region, and the transparent conductive layer having an electrode allocation surface;
a metal electrode, located on the electrode allocation surface;
a light reflective unit, located on the ineffective absorption region, and having a first inclined reflective surface, which is inclined toward the effective absorption region, a horizontal surface, a second inclined reflective surface, and a third reflective surface, the horizontal surface being parallel to the illuminated surface and overlapping a bottom edge of the first inclined reflective surface, a first inclined angle being formed between the first inclined reflective surface and the horizontal surface, the first inclined angle being ranged between 20 degrees and 45 degrees, the second inclined reflective surface being inclined toward the effective absorption region and located opposite to the first inclined reflective surface, a second inclined angle being formed between the second inclined reflective surface and the horizontal surface, the second inclined angle being ranged between 20 degrees and 89 degrees, the third inclined reflective surface being located between the first inclined reflective surface and the second inclined reflective surface, the third inclined reflective surface being inclined away from the effective absorption region, a third inclined angle being formed between the third inclined reflective surface and the horizontal surface, and when a sum of the third inclined angle and double the second inclined angle is greater than 90 degrees, a sum of the third inclined angle and the second inclined angle being ranged between 45 degrees and 70 degrees; and
a transparent packaging layer, located on the transparent conductive layer, the metal electrode and the light reflective unit, and the transparent packaging layer including an interface in contact with air;
wherein, as a light beam propagating along an incident direction perpendicular to the illuminated surface is reflected by the first inclined reflective surface toward the effective absorption region, the light beam is then reflected by the air/transparent-packaging-layer interface, and back to the transparent conductive layer.

2. The solar cell of claim 1, wherein the sum of the third inclined angle and the second inclined angle is ranged between 50 degrees and 65 degrees.

3. The solar cell of claim 1, wherein the semiconductor substrate is a crystalline silicon substrate, the intrinsic semiconductor layer is an intrinsic amorphous silicon layer, the second conductive type semiconductor layer is a second conductive type amorphous silicon layer.

4. The solar cell of claim 1, wherein the light reflective unit is formed on the second conductive type semiconductor layer and located in the ineffective absorption region.

5. The solar cell of claim 1, wherein the intrinsic semiconductor layer is formed on the illuminated surface and located in the effective absorption region, and the light reflective unit is formed on the illuminated surface and located in the ineffective absorption region.

6. The solar cell of claim 1, wherein the metal electrode includes a busbar, and the solar cell further comprises a busbar reflective unit which is located on the busbar.

7. The solar cell of claim 1, wherein the light reflective unit is adhered to the ineffective absorption region.

8. The solar cell of claim 1, wherein the first inclined reflective surface has a reflective coating.

9. The solar cell of claim 8, wherein the reflective coating is selected from a group composed of Al, Ag, Sn, and a composition thereof.

10. A solar cell, comprising:
a semiconductor substrate, doped with a first conductive type dopant, and having an illuminated surface, the illuminated surface including an effective absorption region and an ineffective absorption region surrounding the effective absorption region;
an intrinsic semiconductor layer, formed on the illuminated surface;
a second conductive type semiconductor layer, formed on the intrinsic semiconductor layer, and the second conductive type semiconductor layer being doped with a second conductive type dopant;
a transparent conductive layer, formed on the second conductive type semiconductor layer, and overlapping the effective absorption region, and the transparent conductive layer having an electrode allocation surface;
a metal electrode, located on the electrode allocation surface;
a light reflective unit, located on the ineffective absorption region, and having a first inclined reflective surface, which is inclined toward the effective absorption region, a horizontal surface, a second inclined reflective surface, and a third reflective surface, the horizontal surface being parallel to the illuminated surface and overlapping a bottom edge of the first inclined reflective surface, a first inclined angle being formed between the first inclined reflective surface and the horizontal surface, the first inclined angle being ranged between 20 degrees and 45 degrees, the second inclined reflective surface being inclined toward the effective absorption region and located opposite to the first inclined reflective surface, a second inclined angle being formed between the second inclined reflective surface and the horizontal surface, the second inclined angle being ranged between 20 degrees and 89 degrees, the third inclined reflective surface being located between the first inclined reflective surface and the second inclined reflective surface, the third inclined reflective surface being inclined away from the effective absorption region, a third inclined angle being formed between the third inclined reflective surface and the horizontal surface, and when a sum of the third inclined angle and double the second inclined angle is greater than 90 degrees, a sum of the third inclined angle and the second inclined angle being ranged between 45 degrees and 70 degrees; and
a transparent packaging layer, located on the transparent conductive layer, the metal electrode and the light reflective unit;
wherein, as a light beam propagating along an incident direction perpendicular to the illuminated surface is reflected by the first inclined reflective surface toward the transparent conductive layer.

11. The solar cell of claim 10, wherein the sum of the third inclined angle and the second inclined angle is ranged between 50 degrees and 65 degrees.

12. The solar cell of claim 10, wherein the semiconductor substrate is a crystalline silicon substrate, the intrinsic semiconductor layer is an intrinsic amorphous silicon layer, the second conductive type semiconductor layer is a second conductive type amorphous silicon layer.

13. The solar cell of claim 10, wherein the light reflective unit is formed on the second conductive type semiconductor layer and located in the ineffective absorption region.

14. The solar cell of claim 10, wherein the intrinsic semiconductor layer is formed on the illuminated surface and located in the effective absorption region, and the light reflective unit is formed on the illuminated surface and located in the ineffective absorption region.

15. The solar cell of claim 10, wherein the metal electrode includes a busbar, and the solar cell further comprises a busbar reflective unit which is located on the busbar.

16. The solar cell of claim 10, wherein the light reflective unit is adhered to the ineffective absorption region.

17. The solar cell of claim 10, wherein the first inclined reflective surface has a reflective coating.

18. The solar cell of claim 17, wherein the reflective coating is selected from a group composed of Al, Ag, Sn, and a composition thereof.
